(19) United States
(12) Patent Application Publication
(10) Pub. No.: US 2012/0008393 A1
(43) Pub. Date: Jan. 12, 2012

(54) NONVOLATILE MEMORY DEVICE AND OPERATION METHOD THEREOF

(76) Inventors: Jung-Chul HAN, Gyeonggi-do (KR); Tai-Kyu Kang, Gyeonggi-do (KR)

(21) Appl. No.: 12/974,330

(22) Filed: Dec. 21, 2010

(30) Foreign Application Priority Data
Jul. 7, 2010 (KR) 10-2010-0065389

(51) Int. Cl. G11C 16/16; G11C 16/04; G11C 16/28; G11C 16/34

(52) U.S. Cl. 365/185.11; 365/185.33; 365/185.22; 365/185.2; 365/185.18

(57) ABSTRACT

An operation method of a nonvolatile memory device includes reading information of an erase target block, and performing an erase operation by using a starting erase bias corresponding to the information.

### CROSS-REFERENCE TO RELATED APPLICATIONS

The present application claims priority of Korean Patent Application No. 10-2010-0065389, filed on Jul. 7, 2010, which is incorporated herein by reference in its entirety.

### BACKGROUND OF THE INVENTION

Exemplary embodiments of the present invention relate to a nonvolatile memory device and an erase method of a nonvolatile memory device.

A memory device is commonly categorized as a volatile memory device or a nonvolatile memory device, depending on whether or not data is retained when power is interrupted. The volatile memory device is a memory device which loses data when power is interrupted. Examples of the volatile memory device include a DRAM and an SRAM. The nonvolatile memory device is a memory device which retains data even when power is interrupted. Examples of the nonvolatile memory device include a flash memory device.

Main operations of the nonvolatile memory device include an erase operation, a read operation, and a program operation. If the erase operation and the program operation are repetitively performed on memory cells, physical characteristics of the memory device may be lowered and thus the reliability of cells may be degraded.

FIGS. 1 and 2 illustrate variation in cell characteristics when an erase/program cycle (EP cycle) is repeated.

Specifically, FIG. 1 illustrates a threshold voltage distribution of memory cells after an erase operation is performed using the same erase bias (for example, 20 V). It can be seen from FIG. 1 that the threshold voltage of the cells gradually increases as the erase operation is repeated (i.e., as the number of EP cycles increases). As illustrated in FIG. 1, the increase is more drastic, the smaller the size of the cell is.

FIG. 2 illustrates a threshold voltage distribution of cells within a single block after an erase operation is performed using the same erase bias. Like in FIG. 1, it can be seen that the threshold voltage of the cells within the single block gradually increases as the number of EP cycles increases.

As the repetitions of the EP cycle increases, the threshold voltage of the cells at the same erase bias gradually increases. Hence, it may be difficult to erase cells which have undergone many EP cycles compared to those cells which have not undergone many EP cycles.

FIG. 3 is a flowchart illustrating an erase operation based on a known Incremental Step Pulse Erase (ISPE) scheme.

Referring to FIG. 3, an erase command is inputted at step S301, and a starting erase bias (for example, 18 V) is applied to a corresponding block at step S302. It is verified whether or not an erase operation is completed at step S303. When it is verified that the erase operation is completed, the erase operation is ended at step S305. If the erase operation is not completed, the level of the erase bias is incremented at step S304. The incremented erase bias (for example, a bias whose level is incremented by 1 V from the previous erase bias) is re-applied to the cell at the step S302.

The steps S302 to S304 are repeated until it is verified that the erase operation is completed. Such an erase operation is referred to as an IPSE scheme.

In the case of the memory cells which have undergone a few EP cycles, the erase operation may be completed even if the initial erase bias, 18 V, is applied. However, in the case of the memory cells which have undergone many EP cycles, the erase operation may not be completed without incrementally increasing the erase biases, such as from 18 V to 19 V and then to 20 V.

Therefore, time necessary for the erase operation may increase because of the memory cells which have undergone many EP cycles. Also, the characteristics of memory cells, which have undergone many EP cycles, may deteriorate more rapidly.

### SUMMARY OF THE INVENTION

Exemplary embodiments of the present invention are directed to an operation method of a nonvolatile memory device, which is capable of reducing time necessary for an erase operation and reducing degradation in characteristics of cells caused by the erase operation.

In accordance with an exemplary embodiment of the present invention, an operation method of a nonvolatile memory device includes reading information of an erase target block, and performing an erase operation by using a starting bias corresponding to the information.

In accordance with another exemplary embodiment of the present invention, an operation method of a nonvolatile memory device includes reading information of an erase target block, applying an erase bias corresponding to the information to the erase target block, verifying whether or not the erase target block is erased, re-applying a bias higher than a previous erase bias to the erase target block if the erase target block is not erased, and updating the information with after the erase target block is erased.

In accordance with another exemplary embodiment of the present invention, an operation method of a nonvolatile memory device includes reading first information of a first memory block, applying a first bias corresponding to the first information to the first memory block, reading second information of a second memory block, and applying a second bias corresponding to the second information to the second memory block.

In accordance with another exemplary embodiment of the present invention, a nonvolatile memory device includes a first dummy block configured to store first cycling information of a first block, a second dummy block configured to store second cycling information of a second block, a control unit configured to read the first and second cycling information of the first and second blocks, generate a voltage control signal and update the first and second dummy blocks, and a voltage generator configured to apply a first voltage to the first and second blocks in response to the voltage control signal.

In accordance with another exemplary embodiment of the present invention, a nonvolatile memory device includes a dummy area configured to store cycling information of an erase target block, a control unit configured to read the cycling information of the erase target block, generate a voltage control signal and update the dummy area, and a voltage generator configured to apply a first voltage to the erase target block in response to the voltage control signal.

### BRIEF DESCRIPTION OF THE DRAWINGS

FIGS. 1 and 2 illustrate a variation in cell characteristics after erase/program cycles (EP cycles) are repeated.

FIG. 3 is a flowchart illustrating an erase operation based on a known Incremental Step Pulse Erase (ISPE) scheme.

FIG. 4 is a flowchart illustrating an erase operation of a nonvolatile memory device in accordance with an exemplary embodiment of the present invention.

FIG. 5 is a flowchart illustrating an erase operation of a nonvolatile memory device in accordance with another exemplary embodiment of the present invention.

FIG. 6 illustrates an exemplary block used in an erase operation of a nonvolatile memory device.

FIG. 7 illustrates data areas, each of which is erased respectively by an erase bias determined depending on corresponding cycling information of the data area.

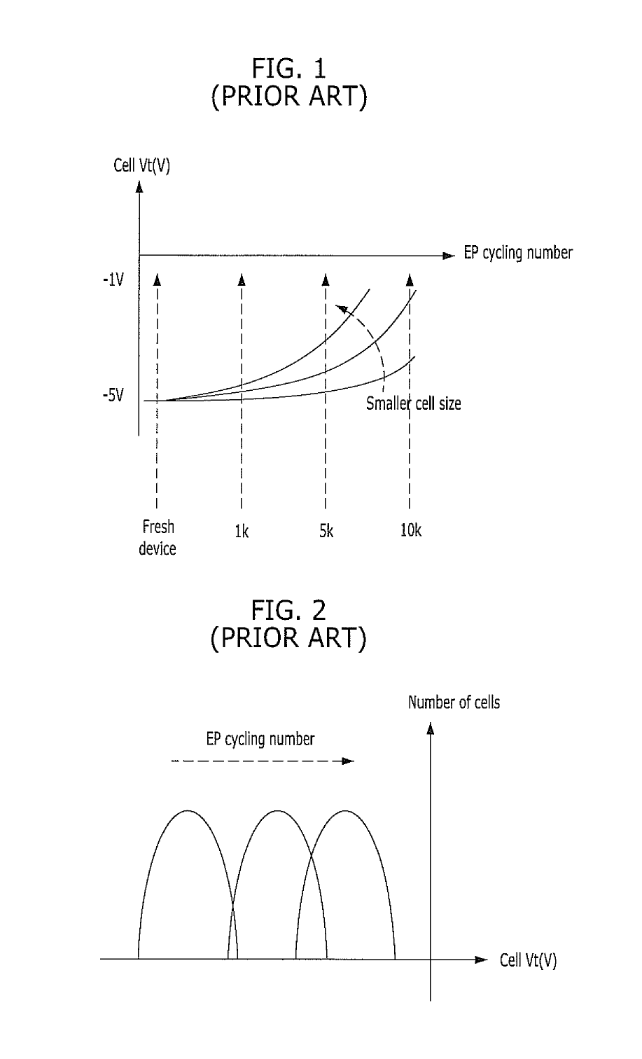

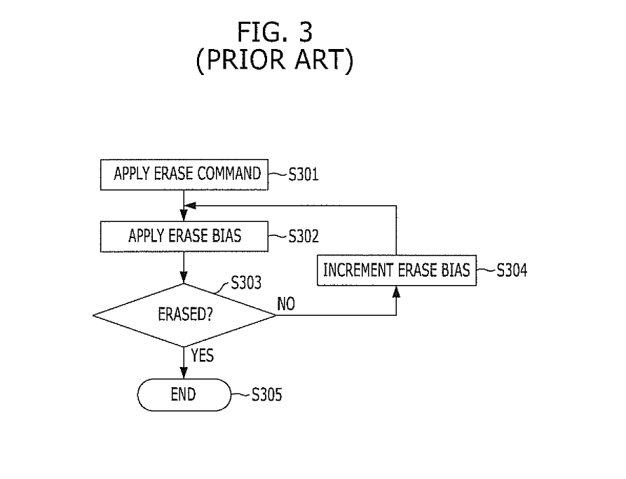

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

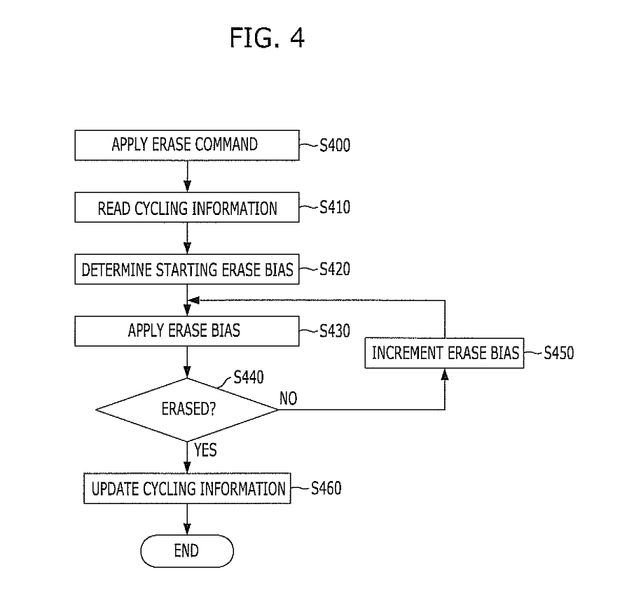

FIG. 4 is a flowchart illustrating an erase operation of a nonvolatile memory device in accordance with an exemplary embodiment of the present invention.

The erase operation of the nonvolatile memory device in accordance with the exemplary embodiment of the present invention includes applying an erase command (step S400), reading cycling information of an erase target block (step S410), determining a starting erase bias (step S420), performing an erase operation by using a bias corresponding to the cycling information as a starting erase bias (step S430), verifying whether a cell is erased (step S440), and incrementing an erase bias if the cell is not erased (step S450). Then updating of the cycling information (step S460) may be performed. The respective steps of the erase method of the nonvolatile memory device will be described in more detail with reference to FIG. 4.

First, an erase command is applied to a nonvolatile memory device at step S400. An erase target block is determined by an address applied corresponding to the erase command, and the nonvolatile memory device reads cycling information of the erase target block at step S410. The cycling information may refer to information indicating how many times the erase target block is erased. For example, the cycling information may be a cycling number. After reading the cycling information of the erase target block, a starting erase bias corresponding to the cycling information is determined at step S420. As the cycling number increases, the starting erase bias increases. For example, if the cycling number is less than 1,000, the starting erase bias may be 18 V. If the cycling number is equal to or greater than 1,000, the starting erase bias may be 19 V. If the cycling number is equal to or greater than 2,000, the starting erase bias may be 20 V.

The starting erase bias, determined at step S420, is applied to the erase target block at step S430. After the step S430, an erase verification operation is performed at step S440 to verify whether or not the erase operation is completed. If the erase verification operation determines that the erase operation is not completed, an erase bias (for example, the erase bias +1 V) higher than the previous erase bias is generated at step S450 and re-applied to the erase target block at step S430. The operations of the steps S430, S440, and S450 are repeated until the erase verification operation is completed.

When the erase verification operation is completed, the cycling information may be updated and stored at step S460, and the erase operation is completed. For example, the cycling number may be stored in a dummy area of the erase target block. The dummy area may be arranged in each block of the nonvolatile memory device. The cycling number of the corresponding block may be recorded in the dummy area.

In accordance with an exemplary embodiment of the present invention, the cycling number of each block is stored in the dummy area of the block, and the starting erase bias of the erase operation is determined depending on the recorded cycling number. Therefore, the erase operation can be performed using an improved starting erase bias corresponding to the cycling number. As a result, the number of applications of the erase bias in the erase operation may be reduced (i.e., the number of repetitions of the steps S430 to S450 may be reduced), thereby reducing the total time of the erase operation.

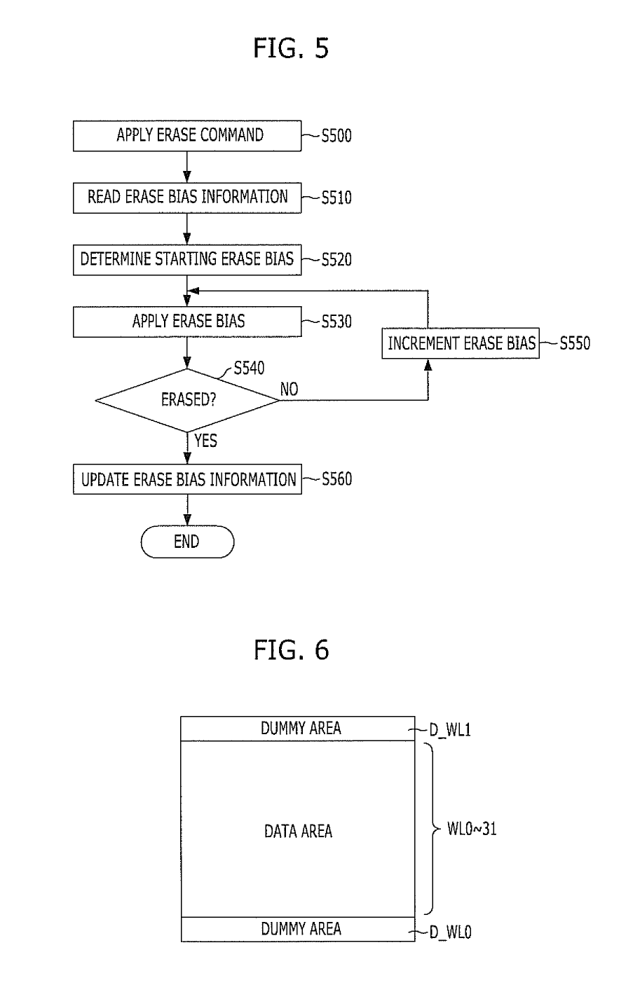

FIG. 5 is a flowchart illustrating an erase operation of a nonvolatile memory device in accordance with another exemplary embodiment of the present invention.

The erase operation in accordance with another exemplary embodiment of the present invention includes reading erase bias information of an erase target block (step S510), applying an erase bias corresponding to the erase bias information to the erase target block (step S530), verifying whether or not the erase operation on the ease target block is completed (step S540), re-applying a bias higher than the previous erase bias to the erase target block if the erase operation is not completed (steps S550 and S530), and updating the erase bias information with the erase bias applied when the erase operation is completed (step S560). The respective steps of the erase operation will be described in more detail with reference to FIG. 5.

First, an erase command is applied to a nonvolatile memory device at step S500. An erase target block is determined by an address applied corresponding to the erase command, and the nonvolatile memory device reads erase bias information of the erase target block at step S510. For example, the erase bias information may refer to an erase bias finally applied in the previous erase operation. After reading the erase bias information of the erase target block, a starting erase bias corresponding to the erase bias information is determined at step S520. The starting erase bias may be equal to the erase bias finally applied in the previous erase operation, or may be slightly lower than the erase bias finally applied in the previous erase operation.

The starting erase bias determined at the steps S510 and S520 is applied to the erase target block at step 530. After the step S530, an erase verification operation is performed at step S540 to verify whether or not the erase operation is completed. If the erase operation is not completed, an erase bias (for example, the erase bias +1 V) higher than the previous erase bias is determined at step S550 and re-applied to the erase target block at step S530. The operations of the steps S530, S540, and S550 are repeated until the erase verification operation is completed.

When the erase verification operation is completed, the erase bias information, which may be the information about the erase bias finally applied in the erase operation, may be updated and stored at step S560, at which point the erase operation is completed. The erase bias information may be stored in a dummy area of the erase target block. The dummy area may be arranged in each block of the nonvolatile memory device. The erase bias information of the corresponding block may be recorded in the dummy area.

In accordance with this exemplary embodiment of the present invention, the erase bias information of each block is stored in the dummy area of the block, and the starting erase bias of the erase operation is determined depending on the recorded erase bias information. Therefore, as the erase bias finally applied in the previous erase operation is higher, the starting erase bias is also set to a higher level. As a result, the erase operation can be performed using an improved starting erase bias. Hence, the number of applications of the erase bias in the erase operation may be reduced (i.e., the number of repetitions of the steps S530 to S550 may be reduced), thereby reducing the total time of the erase operation.

FIG. 6 illustrates an exemplary block used in an erase operation of a nonvolatile memory device.

As shown in FIG. 6, thirty-four word lines may exist in a block. Among them, the thirty-two word lines WL0 to WL31 are word lines used for actually storing data in a data area, and the remaining two word lines D_WL0 and D_WL1 are word lines of a dummy area.

The cycling information or the erase bias information in accordance with the exemplary embodiments of the present invention is recorded in a memory cell coupled to the word line of the dummy area. The cycling information or the erase bias information may be recorded in a single level cell (SLC) scheme. The thirty-two word lines of the data area and the two word lines of the dummy area are merely exemplary, and their number may be variously changed according to the design of the nonvolatile memory device.

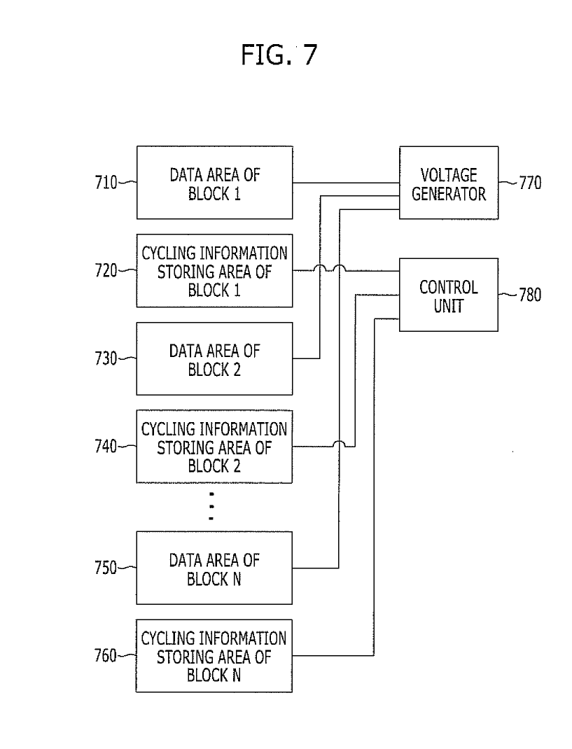

FIG. 7 illustrates data areas, each of which is erased respectively by an erase bias determined depending on corresponding cycling information of the data area.

The cycling information may be stored in a dummy area of each block, and an operation bias of a memory block, for example a starting bias of an operation bias, may be different from an operation bias of another memory block. Each data area (710, 730, and 750) may be operated using the operation bias corresponding to the cycling information stored in a corresponding cycling information storing area (720, 740, and 760). Here, the operation may be an erase operation, or may be a program operation.

Furthermore, as shown in FIG. 7, each of the cycling information storing areas (720, 740, and 760) is coupled to a control unit 780. The control unit 780 determines the bias to be applied to the corresponding data area. Additionally, a voltage generator 770 may be used to generate a voltage to be applied to the corresponding data areas based upon the bias determined by the control unit 780.

In accordance with exemplary embodiments of the present invention, cycling information or bias information is stored for each data area block used in an erase operation.

Therefore, the erase operation may be performed using a more suitable starting erase bias when the erase operation is started. The number of applications of the erase bias may be reduced, thereby reducing the time necessary for the erase operation.

Furthermore, since the number of applications of the erase bias is reduced, a probability of a degradation of the nonvolatile memory device is reduced.

While the present invention has been described with respect to the specific embodiments, it will be apparent to those skilled in the art that various changes and modifications may be made without departing from the spirit and scope of the invention as defined in the following claims.

What is claimed is:

1. An operation method of a nonvolatile memory device, comprising:
reading information of an erase target block; and
performing an erase operation by using a starting erase bias corresponding to the information.

2. The operation method of claim 1, further comprising:
updating the information of the erase target block.

3. The operation method of claim 1, wherein the performing of the erase operation comprises:
applying the starting erase bias to the erase target block;
verifying whether or not the erase target block is erased; and
re-applying a bias higher than a previous erase bias to the erase target block if the erase target block is not erased.

4. The operation method of claim 2, wherein the information is updated by programming the information to a dummy area of the erase target block.

5. The operation method of claim 1, wherein the information is cycling information.

6. The operation method of claim 1, wherein the information is erase bias information.

7. An operation method of a nonvolatile memory device, comprising:
reading information of an erase target block;
applying an erase bias corresponding to the information to the erase target block;
verifying whether or not the erase target block is erased;
re-applying a bias higher than a previous erase bias to the erase target block if the erase target block is not erased; and
updating the information after the erase target block is erased.

8. The operation method of claim 7, wherein the verifying of whether or not the erase target block is erased and the re-applying of the bias higher than the previous erase bias to the erase target block are repeated until the erase target block is erased.

9. The operation method of claim 7, wherein the information is updated by programming the information to a dummy area of the erase target block.

10. The operation method of claim 9, wherein the information is cycling information.

11. The operation method of claim 10, wherein the information is erase bias information.

12. An operation method of a nonvolatile memory device, comprising:
reading first information of a first memory block;
applying a first bias corresponding to the first information to the first memory block;
reading second information of a second memory block; and
applying a second bias corresponding to the second information to the second memory block.

13. The operation method of claim 12, wherein the first and the second bias are erase biases.

14. The operation method of claim 12, wherein the first and the second bias are program biases.

15. The operation method of claim 12, wherein the first information is stored in a dummy area of the first memory block, and wherein the second information is stored in a dummy area of the second memory block.

16. A nonvolatile memory device, comprising:
a first dummy block configured to store first cycling information of a first block;
a second dummy block configured to store second cycling information of a second block;
a control unit configured to read the first and second cycling information of the first and second blocks, generate a voltage control signal and update the first and second dummy blocks; and
a voltage generator configured to apply a first voltage to the first and second blocks in response to the voltage control signal.

17. The nonvolatile memory device of claim 16, wherein the control unit determines a bias voltage, and generates the first voltage to be applied to the first and second blocks based on a determined bias voltage.

18. A nonvolatile memory device, comprising:
a dummy area configured to store cycling information of an erase target block;
a control unit configured to read the cycling information of the erase target block, generate a voltage control signal and update the dummy area; and
a voltage generator configured to apply a first voltage to the erase target block in response to the voltage control signal.

19. The nonvolatile memory device of claim 18, wherein the control unit determines a bias voltage, and generates the first voltage to be applied to the erase target block based on a determined bias voltage.
